(19) United States
(12) Patent Application Publication
(10) Pub. No.: US 2023/0215728 A1
(43) Pub. Date: Jul. 6, 2023

(54) METHODS FOR FORMING A SEMICONDUCTOR STRUCTURE INCLUDING A DIPOLE LAYER

(71) Applicant: ASM IP Holding B.V., Almere (NL)

(72) Inventor: Paul Ma, Scottsdale, AZ (US)

(21) Appl. No.: 18/149,700

(22) Filed: Jan. 4, 2023

Related U.S. Application Data
(60) Provisional application No. 63/296,966, filed on Jan. 6, 2022.

(51) Int. Cl. H01L 21/02; H01L 29/06; H01L 29/20; H01L 29/423; H01L 29/775; H01L 29/66

(52) U.S. Cl. CPC H01L 21/0262; H01L 29/0673; H01L 29/2003; H01L 29/42392; H01L 29/775; H01L 21/0254; H01L 29/66469

(57) ABSTRACT

Methods for forming a semiconductor structure including a gallium nitride dipole layer are disclosed. An exemplary method includes using a cyclical deposition process to deposit a dipole layer comprising gallium nitride over a surface of a gate dielectric. The cyclical deposition process can include providing a gallium precursor to the reaction chamber and separately providing a nitrogen reactant to the reaction chamber. The cyclical deposition process may desirably be a thermal cyclical deposition process. Exemplary structures can include field effect transistor structures, such as gate all around structures.

### CROSS-REFERENCE TO RELATED APPLICATIONS

This application is a nonprovisional of, and claims priority to and the benefit of, U.S. Provisional Patent Application No. 63/296,966, filed Jan. 6, 2022 and entitled “METHODS FOR FORMING A SEMICONDUCTOR STRUCTURE INCLUDING A DIPOLE LAYER,” which is hereby incorporated by reference herein.

### FIELD OF INVENTION

The present disclosure generally relates to methods for forming semiconductor structures including a dipole layer, and particularly to methods for forming semiconductor structures include gallium nitride dipole layers. The present disclosure also generally relates to structures including a gallium nitride based dipole layer.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

For example, one challenge has been finding a suitable conducting material for use as a gate electrode in the CMOS devices. CMOS devices have conventionally used n-type doped polysilicon as the gate electrode material. However, doped polysilicon may not be an ideal gate electrode material for advanced node applications. Although doped polysilicon is conductive, there may still be a surface region which can be depleted of carriers under bias conditions. This region may appear as an extra gate insulator thickness, commonly referred to as gate depletion, and may contribute to the equivalent oxide thickness. While the gate depletion region may be thin, on the order of a few angstroms (Å), the gate depletion region may become significant as the gate oxide thicknesses are reduced in advanced node applications. As a further example, polysilicon does not exhibit an ideal effective work function (eWF) for both NMOS and PMOS devices. To overcome the non-ideal effective work function of doped polysilicon, a threshold voltage adjustment implantation may be utilized. However, as device geometries reduce in advanced node applications, the threshold voltage adjustment implantation processes may become increasingly complex and impractical.

To overcome problems associated with doped polysilicon gate electrodes, the polysilicon gate material may be replaced with an alternative material, such as, for example, a metal containing layer, such as a titanium nitride layer. A titanium nitride layer may provide a more ideal effective work function for CMOS applications. However, in some cases, where higher work function values are desired e.g., in PMOS regions of a CMOS device, improved materials for gate electrodes are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods for forming structures including dipole layers and particularly dipole layers comprising gallium nitride. The dipole layers can be used in a variety of applications, including gate stack layers, logic (e.g., DRAM) electrode layer applications. By way of particular examples, a dipole layer including gallium nitride can be used as a work function adjustment layer.

In accordance with exemplary embodiments of the disclosure, a method of forming a metal-oxide-semiconductor structure is disclosed. Exemplary methods of forming the metal-oxide-semiconductor structure include providing a substrate within a reaction chamber, the substrate comprising a gate dielectric, and performing one or more cycles of a cyclical deposition process to deposit a dipole layer comprising gallium nitride over a surface of the gate dielectric. The cyclical deposition process can include (e.g., sequentially and separately) providing a gallium precursor to the reaction chamber and providing a nitrogen reactant to the reaction chamber. The gallium precursor can include, for example, one or more of a gallium beta diketonate compound, a gallium alkoxide compound, a gallium alkyl compound, a gallium alkylamide compound, a gallium halide compound, and a gallane compound. The gallium precursor can also include, for example, one or more of gallium tris(dimethylamide), gallium(III) acetylacetonate, dimethylgallium isopropoxide, a gallium chloride, triethylgallium, and trimethylgallium. The nitrogen reactant can include, for example, one or more of ammonia, hydrazine, a substituted hydrazine derivative, and a nitrogen-based plasma. In particular examples, the nitrogen reactant can include substituted hydrazine derivatives, such as, one or more of tertbutylhydrazine, methylhydrazine, dimethylhydrazine, and diethylhydrazine

The cyclical deposition process can include one or more of an atomic layer deposition process and a cyclical chemical vapor deposition process. The cyclical deposition process can include a thermal process—i.e., a process that does not use plasma-activated species. In some cases, a reactant can be exposed to a plasma to form activated reactant species.

In accordance with exemplary embodiment, the metal-oxide semiconductor structure can include a gate all around transistor. In addition, the average film thickness of the dipole layer comprising gallium nitride can be between 5 Angstroms and 15 Angstroms, and the dipole layer comprising gallium nitride can induce a threshold voltage shift of between 5 mV and 100 mV per Angstrom thickness of the gallium nitride.

In exemplary embodiments, a method of forming a metal-oxide-semiconductor structure can include depositing a dipole layer comprising gallium nitride over a surface of a gate dielectric. In particular exemplary embodiments, the surface of the gate dielectric can comprise at least one of a high-k dielectric surface or a silicon oxide surface, and the dipole layer comprising gallium nitride can be deposited directly on the surface of the gate dielectric. In further exemplary embodiments, methods for forming a metal-oxide-semiconductor structure can include, performing one or more cycles of an initial cyclical deposition process to deposit an initial dipole layer comprising gallium oxide over the surface of the gate dielectric prior to depositing the dipole layer comprising gallium nitride. According to certain embodiments, the dipole layer comprising gallium nitride can be deposited directly on the initial dipole layer comprising gallium oxide, and the initial dipole layer comprising gallium oxide can be deposited directly on a surface of the gate dielectric. For example, an average film thickness of the initial dipole layer comprising gallium oxide can be between 5 Angstroms and 15 Angstroms.

In accordance with further exemplary embodiments of the disclosure, a semiconductor structure can be formed using the methods as described herein. The semiconductor structure can include a substrate, including a gate dielectric, and a dipole layer comprising gallium nitride formed overlying a surface of the gate dielectric. Exemplary semiconductor structures can further include additional layers, such as one or more additional metal containing layers or conducting layers overlying the dipole layer(s). Exemplary semiconductor structures can further include one or more insulating or dielectric layers underneath the dipole layer. The structure can be or form part of a metal-oxide-semiconductor (MOS) structure, such as one or more of a PMOS and NMOS structure, or other device structure. The structure can also be or form part of a gate stack for a metal-oxide-semiconductor device structures, such as, for example, a gate all around transistor.

In accordance with yet additional embodiments of the disclosure, a device or portion thereof can be formed using a method and/or a structure as described herein. The device can include a substrate, one or more insulating or dielectric layers, a dipole layer comprising gallium nitride overlying the insulating or dielectric layer(s), and an additional metal containing layer overlying the dipole layer. The device can be or form part of, for example, a CMOS device. In further additional embodiments, a device may further include an initial dipole layer comprising gallium oxide overlying the one or more insulating or dielectric layers. In such additional embodiments, the device can include, a gallium nitride layer overlaying a gallium oxide layer, and can further include an additional metal containing layer overlying the dipole layer comprising gallium nitride.

In accordance with yet additional examples of the disclosure, an apparatus configured to perform the methods as described herein and/or to form a structure, device, or portion of either, is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIGS. 1A-B illustrate a method in accordance with exemplary embodiments of the disclosure; and

FIGS. 2-3 illustrate exemplary structures in accordance with embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures suitable for a variety of applications. Exemplary methods can be used, for example, to form dipole layers comprising gallium nitride suitable for metal-oxide-semiconductor (MOS) applications, such as in the formation of complimentary MOS (CMOS) devices. For example, gallium nitride dipole layers can be used in the formation of logic devices, dynamic random-access memory (DRAM), three-dimensional NAND devices. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying or within the substrate, such as one or more layers formed according to a method as described herein. Full devices or partial device portions can be included within or on structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

As used herein, the term “dipole layer” may refer to a layer (or layers) of material that induce a shift in the effective work function of a metal-oxide-semiconductor structure when formed in, on or over a gate dielectric of said metal-oxide-semiconductor structure. For example, a shift in the effective work function of a metal-oxide-semiconductor structure can result in a threshold voltage shift of a transistor comprising said metal-oxide-semiconductor structure.

As used herein, “gallium nitride” is a material that can be represented by a chemical formula that includes gallium and nitrogen. In some embodiments, gallium nitride may not include significant proportions of elements other than gallium and nitrogen. In some embodiments, the gallium nitride comprises GaN. In some embodiments, the gallium nitride may consist essentially of GaN. In some embodiments, the gallium nitride may consist of gallium nitride. A layer consisting of gallium nitride may include an acceptable amount of impurities, such as hydrogen, carbon, chlorine, and/or the like that may originate from one or more precursors used to deposit gallium nitride.

As used herein, “gallium oxide” is a material that can be represented by a chemical formula that includes gallium and oxygen. In some embodiments, gallium oxide may not include significant proportions of elements other than gallium and oxygen. In some embodiments, the gallium oxide comprises GaOₓ. In some embodiments, the gallium oxide may consist essentially of GaOₓ. In some embodiments, the gallium oxide may consist of gallium oxide. A layer consisting of gallium oxide may include an acceptable amount of impurities, such as hydrogen, carbon, chlorine, and/or the like that may originate from one or more precursors used to deposit gallium nitride.

As used herein, a “gallium precursor” includes a gas or a material that can become gaseous and that can be represented by a chemical formula that includes gallium.

As used herein, the term “nitrogen reactant” can refer to a gas or a material that can become gaseous and that can be represented by a chemical formula that includes nitrogen. In some cases, the chemical formula includes nitrogen and hydrogen. In some cases, the nitrogen reactant does not include diatomic nitrogen.

As used herein, the term “gate all around transistor” or “GAA transistor” may refer to a form of metal-oxide-semiconductor structure or MOS device which can include a gate structure (gate stack) which contacts a conductive channel region on all sides, i.e., the gate stack surrounds the conductive channel region. As used herein, the term “gate all around transistor” may also refer to a variety of device architectures such as nanosheet devices, forksheet devices, vertical field effect transistors, stacked device architectures, etc.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The present disclosure may include methods for forming a semiconductor structure including a dipole layer comprising gallium nitride. In more detail, a dipole layer may be employed within a gate stack of a metal-oxide-semiconductor (MOS) device to modulate the effective work function (EWF) of the overall gate stack to improve the performance of the MOS devices. In some embodiments, a dipole layer can be formed, e.g., by a deposition process, over, or directly over the gate dielectric of a metal-oxide-semiconductor (MOS) device, and the properties of the dipole layer (including, but not limited to, material composition, thickness, and deposition method) can alter the band alignment in the MOS device to a provide a device with a preferred operating performance. In particular embodiments, a change in the thickness of a dipole layer disposed over a gate dielectric of a MOS device may induce a significant shift in the threshold voltage of said MOS device. Therefore, in some embodiments, a dipole layer which is relatively inert to thickness changes that could potentially be brought about by subsequent MOS device fabrication processes may be desirable.

Therefore, the present disclosure may include methods for forming a semiconductor structure. In some embodiments, the methods can comprise, providing a substrate including a gate dielectric within a reaction chamber, and performing one or more deposition cycles of a cyclical deposition process to deposit a dipole layer comprising gallium nitride over a surface of the gate dielectric. For example, the cyclical deposition process can include, providing a gallium precursor to the reaction chamber, and providing a nitrogen reactant to the reaction chamber.

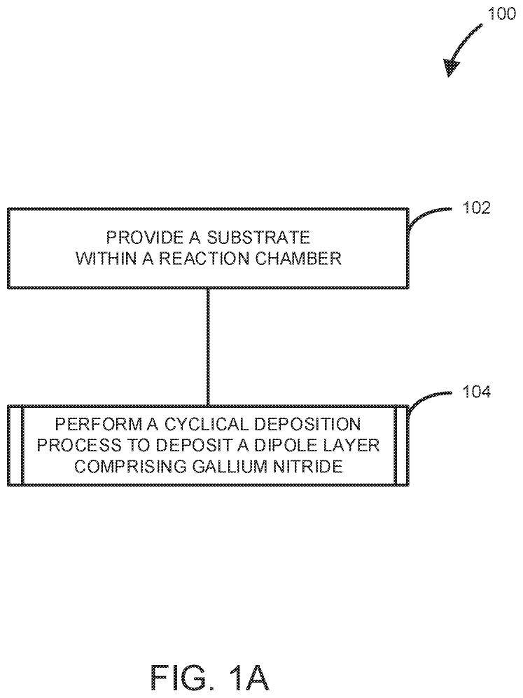

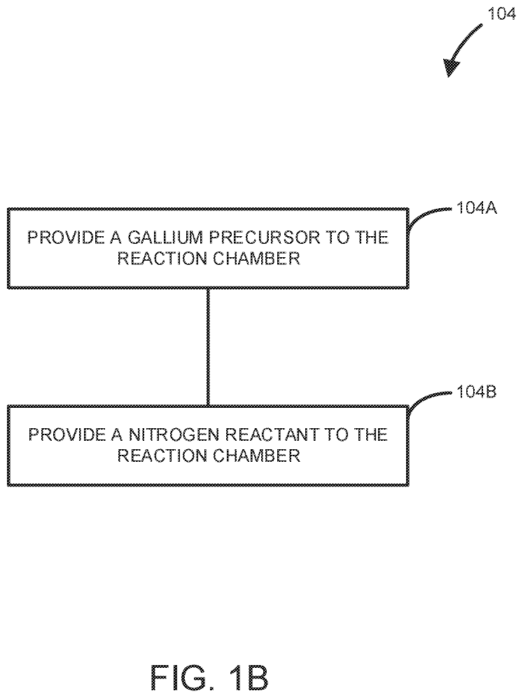

In more detail, FIG. 1A illustrates an exemplary method 100 that can be used to form a semiconductor structure including a dipole layer comprising gallium nitride. In brief, method 100 may include the steps of providing a substrate within a reaction chamber of a reactor (step 102) and by using a cyclical deposition process, depositing a dipole layer comprising gallium nitride onto a surface of the substrate (step 104), and in particular, depositing the dipole layer over a surface of a gate dielectric. In some embodiments, the surface of the gate dielectric may comprise at least one of a high-k dielectric surface or a silicon oxide surface.

In more detail, exemplary method 100 may include step 102 comprising, providing a substrate within a reaction chamber. The reaction chamber employed for step 102 can be, or include, a reaction chamber of a chemical vapor deposition reactor system configured to perform a deposition process. The deposition process may be a chemical vapor deposition process and/or a cyclical deposition process. The reaction chamber can be a standalone reaction chamber or part of a cluster tool. The reaction chamber may be a batch processing tool. In some embodiments, a flow-type reactor may be utilized. In some embodiments, a showerhead-type reactor may be utilized. In some embodiments, a space divided reactor may be utilized. In some embodiments, a high-volume manufacturing-capable single wafer reactor may be utilized. In other embodiments, a batch reactor comprising multiple substrates may be utilized. For embodiments in which a batch reactor is used, the number of substrates may be in the range of 10 to 200, or 50 to 150, or even 100 to 130. The reactor can be configured as a thermal reactor—with no plasma excitation apparatus. Alternatively, the reactor can include direct and/or remote plasma apparatus.

The substrate disposed within the reaction chamber may be heated to a desired deposition temperature for a subsequent deposition. For example, the substrate may be heated to a substrate temperature of less than approximately 800° C., or less than approximately 600° C., or less than approximately 400° C., or even less than approximately 200° C. In some embodiments of the disclosure, the substrate temperature during step 102 may be greater than room temperature, between approximately 200° C. and approximately 800° C., or between approximately 200° C. and approximately 600° C., or between approximately 200° C. and approximately 400° C. The temperature during step 104 (i.e., the cyclical deposition process) can also be within these ranges.

In addition to controlling the temperature of the substrate, the pressure in the reaction chamber may also be regulated to enable deposition of desired dipole layer. For example, in some embodiments of the disclosure, the pressure within the reaction chamber may be less than 760 Torr, or between 0.1 Torr and 10 Torr, or between 0.5 Torr and 5 Torr, or between 1 Torr to 4 Torr.

Once the temperature of the substrate has been set to the desired deposition temperature and pressure in the reaction chamber has been regulated as desired, method 100 may continue to step 104, which comprises using a cyclical deposition process to deposit a dipole layer comprising gallium nitride over a surface of a substrate. For example, the embodiments of the present disclosure, may comprise, performing one or more deposition cycles of a cyclical deposition process to deposit a dipole layer comprising gallium nitride over a surface of a substrate, and particularly over a surface of a gate dielectric.

FIG. 1B illustrates the exemplary cyclical deposition process of step 104 and its component sub-steps 104A and 104B employed for depositing the dipole layers of the present disclosure. In brief, the cyclical deposition process 104 (FIG. 1B), may comprise providing a gallium precursor to the reaction chamber (sub-step 104A) and providing a nitrogen reactant to the reaction chamber (sub-step 104B). The gallium precursor and the nitrogen reactant can be separately and/or sequentially provided to the reaction chamber, with or without intervening reaction chamber purge sequences. The sub-steps 104A and 104B (and any intervening purge sequences) may constitute a deposition cycle and a deposition cycle may be repeated one or more times to deposit a dipole layer comprising gallium nitride to a desired thickness over the substrate, and particularly over a gate dielectric.

In more detail, sub-step 104A comprises providing a gallium precursor to the reaction chamber. The gallium precursor can be pulsed to the reaction chamber. The term “pulse” can be understood to comprise feeding a precursor into the reaction chamber for a predetermined amount of time. Unless otherwise noted, the term “pulse” does not restrict the length or duration of the pulse and a pulse may be any length of time. The gallium precursor pulse may be supplied to the reaction chamber along with a carrier gas flow. In some embodiments, the gallium precursor may comprise a volatile gallium species that is reactive with the surface(s) of the substrate. The gallium precursor pulse may self-saturate the substrate surfaces such that excess constituents of the gallium precursor pulse do not further react with the molecular layer formed by this process.

The gallium precursor pulse is preferably supplied as a vapor phase reactant. The gallium precursor gas may be considered “volatile” for the purposes of the present disclosure if the species exhibits sufficient vapor pressure under the process conditions to transport species to the substrate surface in sufficient concentration to saturate the exposed surfaces.

In accordance with some embodiments of the disclosure, the gallium precursor can include one or more of a gallium halide compound, a gallium oxyhalide compound, a gallium organometallic compound, a gallium metal organic compound, or the like.

In some embodiments of the disclosure, the gallium precursor may comprise one or more of a gallium beta diketonate compound, a gallium alkoxide compound, a gallium alkyl compound, a gallium alkylamide compound, a gallium halide compound, and a gallane compound. For example, the gallium precursor may comprise one or more gallium beta diketonates compounds, such as, for example, gallium tris-acetylacetonate, and tris(2,2,6,6-tetramethyl-3,5-heptanedionato)gallium(III). The gallium precursor may also comprise one or more gallium alkyl compounds, such as, for example, triethylgallium (TEG), and trimethylgallium (TMG). The gallium precursor may also comprise one or more gallium alkylamide compounds, such as, gallium tris(dimethylamide) (TDMAGa), for example. The gallium precursor may comprise one or more gallium halide compounds, such as gallium monochloride, gallium trichloride, gallium tribromide, and gallium tri-iodide.

As a non-limiting example, the gallium precursor may comprise gallium tris(dimethylamide), gallium(III) acetylacetonate (Ga(acac)₃), gallium alkoxides, such as dimethylgallium isopropoxide, and/or gallium alkyls, such as, trimethylgallium (TMGa). In some embodiments, carboxylates of gallium can be used as precursors, for example, gallium triacetate or gallium tripropionate.

In some embodiments of the disclosure, the gallium precursor may be pulsed to the reaction chamber for a time period sufficient to form a monolayer or a sub-monolayer of a gallium species on a surface of the substrate. Subsequently, excess gallium precursor may be purged by stopping the flow of the gallium precursor while continuing to flow a carrier gas, a purge gas, or a gas mixture, for a sufficient time to diffuse or purge excess precursor and any reactant by-products from the reaction chamber. Provision and removal of the gallium precursor may be considered as the first or “gallium phase” of the cyclical deposition process 104 (FIG. 1B).

The cyclical deposition process 104 (FIG. 1B) may continue by providing a nitrogen reactant to the reaction chamber (sub-step 104B). Exemplary nitrogen reactants can be selected from one or more of ammonia (NH₃), hydrazine (N₂H₄), other nitrogen and hydrogen-containing gases (e.g., a mixture of nitrogen gas and hydrogen gas), and the like. The nitrogen reactant can include or consist of nitrogen and hydrogen. In some cases, the nitrogen reactant does not include diatomic nitrogen.

In some embodiments, the nitrogen reactant comprises a substituted hydrazine compound. For example, during sub-step 104B, a nitrogen reactant comprising a substituted hydrazine compound can be provided to the reaction chamber. In some embodiments, the substituted hydrazine compound may comprise an alkyl-hydrazine selected from the group consisting of: tertbutylhydrazine (C₄H₉N₂H₃), methylhydrazine (CH₃NHNH2), dimethylhydrazine (C₂H₈N₂) and diethylhydrazine (C₄H₁₂N₂). In some embodiments of the disclosure, the substituted hydrazine compound may comprise one or more of 1,1-diethylhydrazine, 1-ethyl-1-methylhydrazine, isopropylhydrazine, phenylhydrazine, 1,1-diphenylhydrazine, 1,2-diphenylhydrazine, N-methyl-N-phenylhydrazine, 1,1-dibenzylhydrazine, 1,2-dibenzylhydrazine, 1-ethyl-1-phenylhydrazine, 1-methyl-1-(m-tolyl)hydrazine, and 1-ethyl-1-(p-tolyl)hydrazine.

In some embodiments, the nitrogen reactant may be pulsed to the reaction chamber as previously described in relation to the gallium precursor, and after sufficient time to completely saturate and react the previously absorbed molecular layer with the nitrogen reactant, any excess reactant, and reaction byproducts may be removed from the reaction chamber. As with the removal of the gallium precursor reactant, this step may comprise stopping flow of the nitrogen reactant to the reaction chamber while continuing to flow a carrier gas, a purge gas, or a gas mixture, for a sufficient time to diffuse or purge excess reactants and reactant by-products, if any, from the reaction chamber.

In some embodiments of the disclosure, the cyclical deposition process 104 (FIG. 1B) comprises a deposition cycle that includes (1) providing a gallium precursor to the reaction chamber (sub-step 104A) and (2) providing a nitrogen reactant to the reaction chamber (sub-step 104B), with optional purge or move steps after step (1) and/or step (2). The deposition cycle can be repeated multiple times, the number of repetitions being decided based on, for example, the desired thickness of the dipole layer to be deposited, e.g., the desired thickness of the gallium nitride dipole layer. For example, if the thickness of the gallium nitride dipole layer is less than desired for a particular application, then the step of providing a gallium precursor to the reaction chamber and providing a nitrogen reactant to the reaction chamber can be repeated one or more times. Once the dipole layer comprising gallium nitride has been deposited to a desired thickness, the substrate can be subjected to additional processes to form a desired structure and/or device, such as, a metal-oxide-semiconductor device, for example.

In some embodiments, method 100 may comprise performing multiple deposition cycles of the cyclical deposition process 104 to deposit a dipole layer comprising gallium nitride over a surface of a gate dielectric. For example, the repeated deposition cycles may deposit a dipole layer comprising gallium nitride having an average layer thickness between approximately 5 Å and approximately 15 Å. In addition, the dipole layer comprising gallium nitride may be deposited over a gate dielectric with a the step coverage equal to or greater than about 50%, or greater than about 80%, or greater than about 90%, or about 95%, or about 98%, or about 99% or greater.

While exemplary cyclical deposition process 104 (FIG. 1B) is generally referred to herein as beginning with the gallium phase, it is contemplated that in other embodiments, a deposition cycle may begin with the nitrogen phase. One of skill in the art will recognize that the first precursor phase generally reacts with the termination left by the last phase in the previous cycle. Thus, while no reactant may be previously absorbed on the substrate surface or present in the reaction chamber if the nitrogen is the first phase in a deposition cycle, in subsequent cycles, the reactive species phase will effectively follow the gallium phase. In some embodiments, one or more different cycles (e.g., different times, precursors, flowrates, or the like) are provided in method 100.

In accordance with some examples of the disclosure, the cyclical deposition process 104B (FIG. 1B) can comprise a thermal deposition process. For example, the cyclical deposition process 104 may comprise one or more of a thermal atomic layer deposition process, or a thermal cyclical chemical vapor deposition process. In these cases, the thermal cyclical deposition process does not include the use of a plasma to form activated species for use in the cyclical deposition process. For example, the cyclical deposition process may not comprise formation or use of a nitrogen plasma, may not comprise formation or use of excited nitrogen species, and/or may not comprise formation or use of nitrogen radicals.

Alternatively, in accordance with some embodiments of the disclosure, the use of a plasma to form activated species (or reactants) may be employed during step 104 for depositing a dipole layer comprising gallium nitride, such as, for example, by the generation of a nitrogen based plasma.

In some embodiments, method 100 (FIG. 1A) may include additional steps. As non-limiting examples, method 100 may include additional steps prior to the cyclical deposition of the gallium nitride dipole layer and/or additional steps subsequent to the cyclical deposition of the gallium nitride dipole layer.

In some embodiments, method 100 may include additional steps prior to the cyclical deposition of the gallium nitride dipole layer. As a non-limiting example, additional steps of method 100 prior to depositing the gallium nitride dipole layer may include depositing an initial dipole layer directly on the surface of the substrate. In some embodiments, the initial dipole layer may comprise a gallium oxide dipole layer deposited by an initial cyclical deposition process and the gallium oxide dipole layer may be deposited directly on a surface of a gate dielectric. In such embodiments, the method 100 may further comprise, performing one or more deposition cycles of an initial cyclical deposition process to deposit an initial dipole layer comprising gallium oxide over the surface of a gate dielectric prior to depositing the dipole layer comprising gallium nitride The method 100 may further comprise depositing the dipole layer comprising gallium nitride directly over the initial dipole layer comprising gallium oxide.

In some embodiments, method 100 may include additional steps subsequent to the cyclical deposition of the gallium nitride dipole layer. As a non-limiting example, the additional steps of method 100 subsequent to the depositing the gallium nitride dipole layer may comprise depositing a metal-containing layer directly on the dipole layer comprising gallium nitride, wherein the metal-containing layer is deposited utilizing a halide-containing metal precursor.

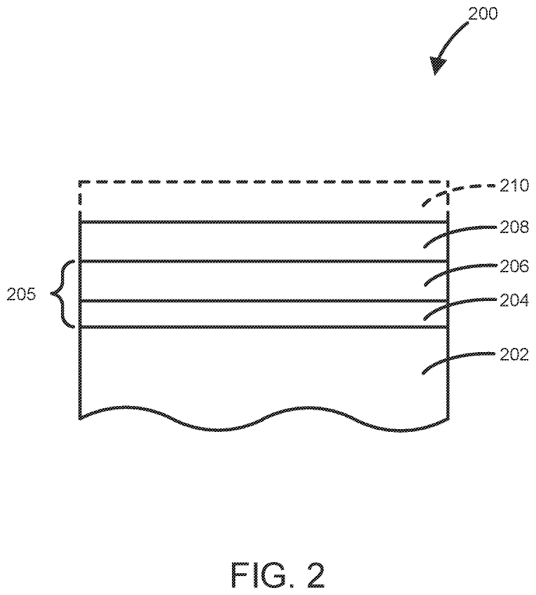

FIG. 2 illustrates a structure/a portion of a device 200 in accordance with additional embodiments of the disclosure. Device or structure 200 includes a substrate 202, dielectric or insulating material 205, and a dipole layer 208 comprising gallium nitride. In the illustrated example, structure 200 also includes an additional conducting layer 210, such as, a metal-containing layer, for example.

Substrate 202 can be or include any of the substrate materials described herein.

Dielectric or insulating material 205 can include one or more dielectric or insulating material layers. By way of example, dielectric or insulating material 205 can include an interface layer 204 and a high-k material 206 deposited overlying interface layer 204. In some cases, interface layer 204 may not exist or may not exist to an appreciable extent. Interface layer 204 can include an oxide, such as a silicon oxide, which can be formed on a surface of the substrate 202 using, for example, a chemical oxidation process or an oxide deposition process. High-k material 206 can be or include, for example, a metallic oxide having a dielectric constant greater than about 7. In some embodiments, the high-k material has a dielectric constant higher than the dielectric constant of silicon oxide. Exemplary high-k materials include one or more of hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and mixtures/laminates comprising one or more such layers.

The dipole layer 208 comprising gallium nitride can be formed according to processes described herein. In some cases, the dipole layer 208 can have a stochiometric composition. A work function and other properties of dipole layer 208 comprising gallium nitride can be altered by altering deposition parameters during in a deposition cycle.

The dipole layer 208 comprising gallium nitride can include impurities, such as halides, hydrogen or the like in an amount of less than one atomic percent, less than 0.2 atomic percent, less than 0.1 atomic percent, or less than 0.05 atomic percent, alone or combined.

The average layer thickness of dipole film 208 comprising gallium nitride can vary according to the desired application. In some exemplary embodiments, an average layer thickness of the dipole layer comprising gallium nitride can be between approximately 5 A and approximately 15 A.

Structure/a portion of a device 200 may further include an additional conducting layer 210, for example a metal, such as a refractory metal or the like. By way of examples, conducting layer 210 can be or include one or more of titanium nitride; vanadium nitride; a metal stack including titanium nitride and a metal (e.g., W, Co, Ru, Mo) or titanium nitride, titanium aluminum carbon, and titanium nitride; tungsten; tungsten carbon nitride; cobalt; copper; molybdenum; ruthenium; or the like.

Although illustrated with gallium nitride dipole layer 208 overlying dielectric or insulating material 205, in some cases, the dipole layer 208 can additionally or alternatively be formed directly over substrate 202 (which can include various layers and/or topologies) and/or underlying dielectric or insulating material 205, between interface layer 204 and high-k material 206, and/or between layers of high-k material 206.

In some embodiments, the dipole layer 208 comprising gallium nitride may induce a threshold shift in a MOS type device fabricated from a structure as illustrated in FIG. 2. In some embodiments, a dipole layer comprising gallium nitride may induce a threshold voltage shift of between 5 mV and 100 mV per angstrom of thickness of the gallium nitride dipole layer. In some embodiments, an effective work function of a device incorporating a gallium nitride dipole layer deposited according to the methods of the present disclosure may be shifted by about 30 meV to about 400 meV, or about 30 meV to about 200 meV, or about 50 meV to about 100 meV. A thickness and/or composition of the gallium nitride dipole layer 208 can be manipulated to obtain a desired shift in work function and/or threshold voltage.

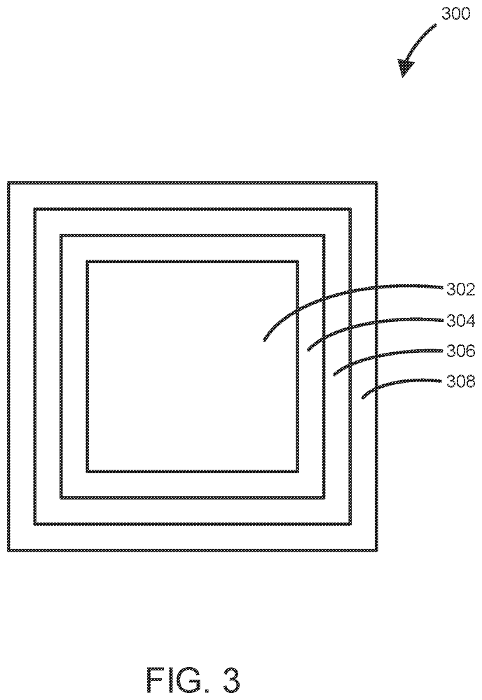

FIG. 3 illustrates another structure 300 in accordance with examples of the disclosure. Structure 300 is suitable for gate all around field effect transistors (GAA FET) (also referred to as lateral nanowire FET) devices and the like. In the illustrated example, structure 300 includes semiconductor material 302, dielectric material 304, a gallium nitride dipole layer 306, and a conducting layer 308. Structure 300 can be formed overlying a substrate, including any substrate materials described herein.

Semiconductor material 302 can include any suitable semiconducting material. For example, semiconductor material 302 can include Group IV, Group III-V, or Group II-VI semiconductor material. By way of example, semiconductor material 302 includes silicon.

Dielectric material 304, gallium nitride dipole layer 306, and conducting layer 308 can be the same or similar to dielectric or insulating material 205, gallium nitride dipole layer 208 and conducting layer 210, described above. The dipole layer comprising gallium nitride 406 can be formed overlying semiconductor material 302 and/or underlying dielectric material 304 in accordance with further examples of the disclosure.

Embodiments of the disclosure may further comprise semiconductor structure formed according to the methods as described here.

Embodiments of the disclosure may further comprise apparatus configured for performing the methods as described herein.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a semiconductor structure, the method comprising:
providing a substrate within a reaction chamber, the substrate comprising a gate dielectric; and
performing one or more deposition cycles of a cyclical deposition process to deposit a dipole layer comprising gallium nitride over a surface of the gate dielectric, wherein the cyclical deposition process comprises:
providing a gallium precursor to the reaction chamber; and
providing a nitrogen reactant to the reaction chamber.

2. The method claim 1, wherein the gallium precursor comprises one or more of a gallium beta diketonate compound, a gallium alkoxide compound, a gallium alkyl compound, a gallium alkylamide compound, a gallium halide compound, and a gallane compound.

3. The method of claim 1, wherein the gallium precursor comprises one or more of gallium tris(dimethylamide), gallium(III) acetylacetonate, dimethylgallium isopropoxide, gallium monochloride, gallium trichloride, gallium triiodide, triethylgallium, and trimethylgallium.

4. The method of claim 1, wherein the nitrogen reactant comprises one or more of ammonia, hydrazine, a substituted hydrazine derivative, and a nitrogen-based plasma.

5. The method of claim 1, wherein the substituted hydrazine derivative comprises one or more of tertbutylhydrazine, methylhydrazine, dimethylhydrazine, and diethylhydrazine.

6. The method of claim 1, wherein the cyclical deposition process comprises one or more of a thermal atomic layer deposition process, or a thermal cyclical chemical vapor deposition process.

7. The method of claim 1, wherein the semiconductor structure comprises a gate all around transistor.

8. The method of claim 1, wherein an average layer thickness of the dipole layer comprising gallium nitride is between 5 Å and 15 Å.

9. The method of claim 1, wherein the dipole layer comprising gallium nitride induces a threshold voltage shift of between 5 mV and 100 mV per A thickness of the gallium nitride.

10. The method of claim 1, further comprising:
depositing a metal containing layer directly on the dipole layer comprising gallium nitride, wherein the metal containing layer is deposited utilizing a halide containing metal precursor.

11. The method of claim 1, wherein the surface of the gate dielectric comprises at least one of a high-k dielectric surface or a silicon oxide surface.

12. The method of claim 1, wherein the dipole layer comprising gallium nitride is deposited directly on a surface of the gate dielectric.

13. The method of claim 1, further comprising:
performing one or more deposition cycles of an initial cyclical deposition process to deposit an initial dipole layer comprising gallium oxide over the surface of the gate dielectric prior to depositing the dipole layer comprising gallium nitride.

14. The method of claim 13, wherein the dipole layer comprising gallium nitride is deposited directly on the initial dipole layer comprising gallium oxide.

15. The method of claim 13, wherein an average film thickness of the initial dipole layer comprising gallium oxide is between 5 Å and 15 Å.

16. A semiconductor structure formed according to the method of claim 1.

17. A semiconductor structure formed according to the method of claim 13.

18. An apparatus configured for performing the methods of claim 1.

19. An apparatus configured for performing the methods of claim 13.
